(19) United States
(12) Patent Application Publication
(10) Pub. No.: US 2025/0380355 A1
(43) Pub. Date: Dec. 11, 2025

(54) WIRING SUBSTRATE

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Sheng-Fan YANG, HSINCHU CITY (TW); Jing-Hua CHENG, HSINCHU CITY (TW); Po-Ning KO, HSINCHU CITY (TW); Yao-Tsu CHEN, HSINCHU CITY (TW); Chi-Ming YANG, HSINCHU CITY (TW); Chi-Lou YEH, HSINCHU CITY (TW); Ming-Ya CHAN, HSINCHU CITY (TW)

(21) Appl. No.: 18/923,719

(22) Filed: Oct. 23, 2024

(30) Foreign Application Priority Data
Jun. 11, 2024 (TW) 113121529

(51) Int. Cl. H05K 1/02; H05K 1/11; H05K 1/18

(52) U.S. Cl. CPC H05K 1/0271; H05K 1/0218; H05K 1/113; H05K 1/181; H05K 2201/0939; H05K 2201/09409; H05K 2201/09481; H05K 2201/09618; H05K 2201/09781; H05K 2201/09854

(57) ABSTRACT

A wiring substrate includes a main ground area, a multi-layer board structure, a wiring module and a plurality of dummy metal pads. The multilayer board structure is divided into an upper portion and a lower portion through a core layer therein. The main ground area is located in the lower portion. The wiring module includes a plurality of ground via portions electrically connected to the main ground area respectively, and a differential pair circuit having two signal via portions arranged among the ground via portions. These dummy metal pads are embedded in the lower portion at intervals, electrically isolated from the wiring module, spaced arranged between the differential pair circuit and the ground via portions, and between the signal via portions.

### RELATED APPLICATIONS

This application claims priority to Taiwanese Application Serial Number 113121529, filed Jun. 11, 2024, which are herein incorporated by reference.

### BACKGROUND

The present disclosure relates to a wiring substrate. More particularly, the present disclosure relates to a wiring substrate capable of striking a balance between the stress and the signal integrity of a substrate structure.

### Description of Related Art

In general, a substrate structure of a traditional semiconductor device is stacked with multiple boards, and each of these multiple boards is formed with circuit patterns and via portions thereon. The respective pattern circuits of these boards are connected to each other through the via portions, and connected to other electronic units through the via portions.

However, during a high-speed signal array (e.g., Serializer/Deserializer, SerDes) is designed, when the substrate structure of a semiconductor device is optimized for stress during testing, the signal integrity of its signal channel is often correspondingly reduced. On the contrary, when pursuing high signal integrity of the signal channel of the substrate structure, the stress of the substrate structure is weakened, thereby increasing the risk of damage. Therefore, designers are often in a dilemma to strike a balance between the stress and the signal integrity of the substrate structure.

### SUMMARY

One aspect of the present disclosure is to provide a wiring substrate to solve the aforementioned problems of the prior art.

In one embodiment of the present disclosure, a wiring substrate is provided, and includes a multilayer board structure, a main ground area, a wiring module and a plurality of first dummy metal pads. The multilayer board structure is divided into an upper portion and a lower portion by a core layer interposed therein. The upper portion is used to connect to a die device, and the lower portion is used to connect to a circuit board. The main ground area is located within the lower portion of the multilayer board structure. The wiring module is located on the multilayer board structure, and includes a differential pair circuit and a plurality of ground via portions. The ground via portions are electrically connected to the main ground area, respectively. The differential pair circuit includes two signal via portions arranged among the ground via portions. The first dummy metal pads are embedded in the lower portion, electrically isolated from the wiring module, spaced arranged between the differential pair circuit and the ground via portions, and between the signal via portions.

In one embodiment of the present disclosure, a wiring substrate is provided, and includes a multilayer board structure, a main ground area and a wiring module. The multilayer board structure includes a core layer, a first solder mask layer, a second solder mask layer, at least one first dielectric layer and at least one second dielectric layer. The core layer is stacked between the first dielectric layer and the second dielectric layer. A thickness of the core layer that is greater than a thickness of the second dielectric layer. The first dielectric layer is stacked between the first solder mask layer and the core layer. The first solder mask layer is used to install a solder bump layer thereon, the second dielectric layer is stacked between the second solder mask layer and the core layer. The second solder mask layer is used to arrange a BGA layer thereon. The second dielectric layer includes a first layer body and a plurality of first dummy metal pads embedded within the first layer body and spaced arranged within the first layer body in a plane direction. The main ground area is located within the multilayer board structure. The wiring module includes a differential pair circuit and a plurality of ground via portions. Each of the ground via portions penetrates through the multilayer board structure, and is electrically connected to the solder bump layer, the BGA layer and the main ground area, respectively. The differential pair circuit includes two signal via portions. Each of the signal via portions penetrates through the multilayer board structure, is arranged among the ground via portions, and electrically connected to the solder bump layer and the BGA layer. The first dummy metal pads are electrically isolated from the wiring module, and separated from the differential pair circuit and the ground via portions, respectively.

In one embodiment of the present disclosure, a wiring substrate is provided, and includes a multilayer board structure, a main ground area, a wiring module and a plurality of dummy metal pads. The multilayer board structure is divided into an upper portion and a lower portion by a core layer interposed therein. The upper portion is used to connect to a die device, and the lower portion includes a solder mask layer, a BGA layer and at least one dielectric layer. The dielectric layer is stacked between the solder mask layer and the core layer. The solder mask layer is located between the BGA layer and the dielectric layer. The BGA layer is used to connect to a circuit board. The main ground area is located within the lower portion of the multilayer board structure. The wiring module includes a differential pair circuit and a plurality of ground via portions. Each of the ground via portions penetrates through the multilayer board structure and is electrically connected to the main ground area. The differential pair circuit includes two signal via portions. Each of the signal via portions penetrates through the multilayer board structure, is arranged among the ground via portions. The dummy metal pads are embedded in one of the solder mask layer and the dielectric layer, and arranged sequentially in a plane direction. The dummy metal pads are spaced arranged between the differential pair circuit and the ground via portions, and between the signal via portions, and electrically isolated from the wiring module.

Thus, through the construction of the embodiments above, as metal being broken into a plurality of dummy metal pads distributed at intervals around the wiring module in the wiring substrate, the wiring substrate of the disclosure is able to strike a balance between the stress and the signal integrity of the substrate structure so as to not only reduce the risk of damage to the wiring substrate, but also maintain signal transmission performance conforming to requirements.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is a schematic side view of a wiring substrate according to an embodiment of the present disclosure.

FIG. 2 is a cross-sectional view of the wiring substrate viewed along a line AA in FIG. 1.

FIG. 3 is a cross-sectional view of the wiring substrate viewed along a line BB in FIG. 1.

FIG. 4 is a schematic side view of a wiring substrate according to an embodiment of the present disclosure.

FIG. 5 is a frequency-intensity table of various wiring substrates.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

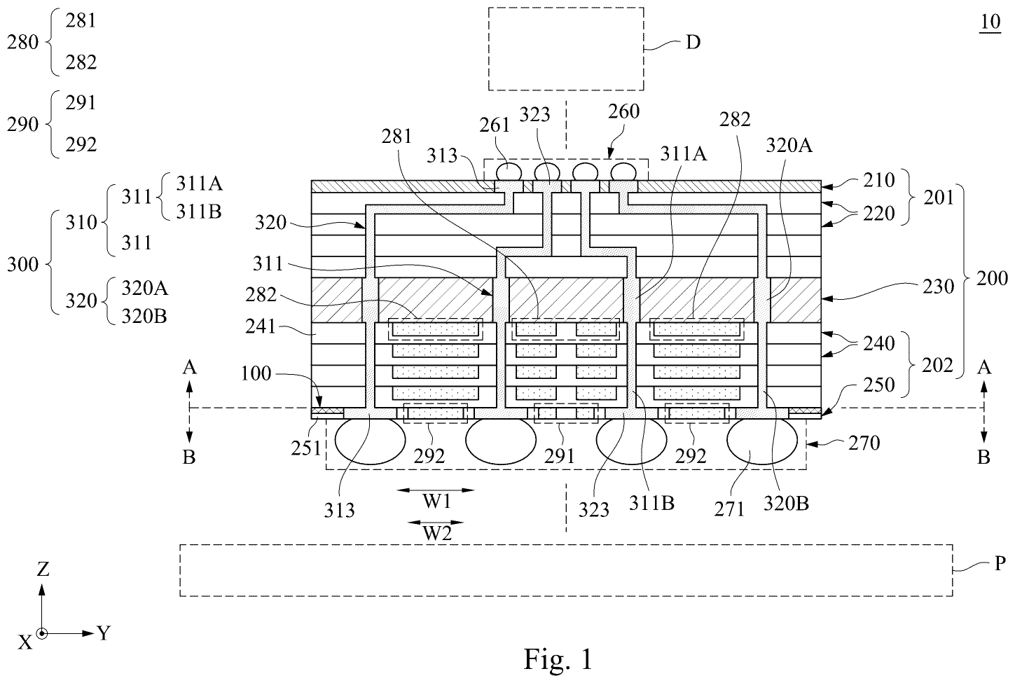

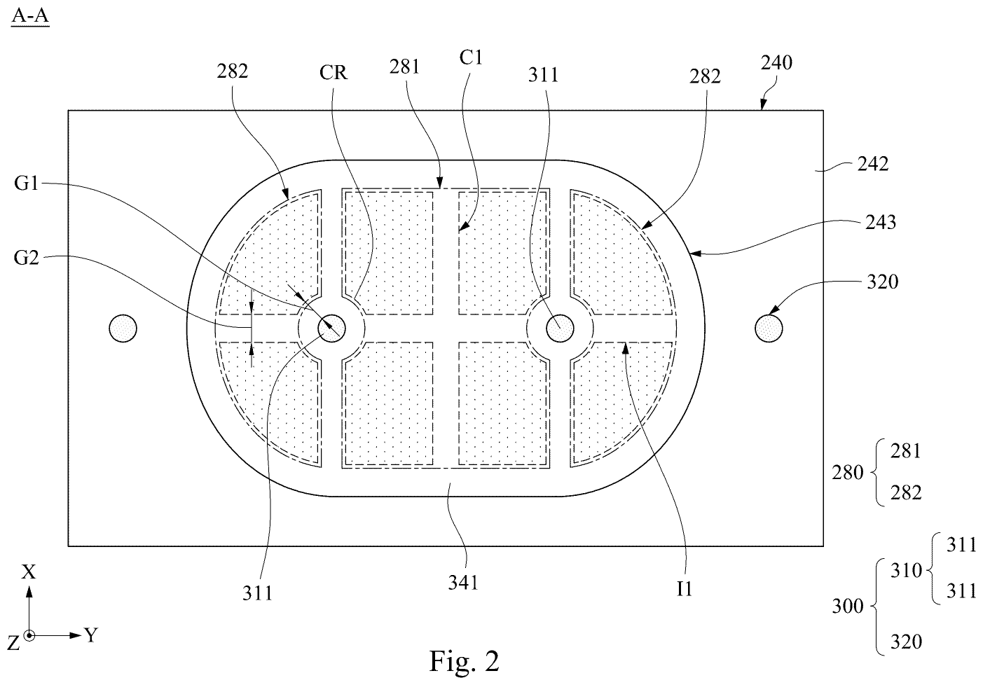

Reference is now made to FIG. 1 and FIG. 2 in which FIG. 1 is a schematic side view of a wiring substrate 10 according to an embodiment of the present disclosure, and FIG. 2 is a cross-sectional view of the wiring substrate 10 in FIG. 1 viewed along a line AA. As shown in FIG. 1 and FIG. 2, the wiring substrate 10 includes a main ground area 100, a multilayer board structure 200 and a wiring module 300. The multilayer board structure 200 includes a core layer 230 extending in a plane direction (e.g., X-Y axis direction), and the multilayer board structure 200 is divided into an upper portion 201 and a lower portion 202 by the core layer 230 interposed therein. The upper portion 201 is used to connect to a die device D, and the lower portion 202 is used to connect to a circuit board P. The upper portion 201, the core layer 230 and the lower portion 202 are sequentially stacked along a stacking direction (e.g., Z axis direction), and the stacking direction is orthogonal to the plane direction (e.g., X-Y axis direction).

More specifically, the multilayer board structure 200 includes a first solder mask layer 210, a second solder mask layer 250, a plurality of first dielectric layers 220, a plurality of second dielectric layers 240 and the aforementioned core layer 230. The aforementioned core layer 230 is sandwiched between the first dielectric layers 220 and the second dielectric layers 240, and a thickness of the core layer 230 is greater than a thickness of each of the second dielectric layers 220 or a thickness of each of the first dielectric layers 220. The first dielectric layers 220 are stacked sequentially along the stacking direction (e.g., Z axis direction) and directly sandwiched between the core layer 230 and the first solder mask layer 210. The first solder mask layer 210 is a topmost layer of the multilayer board structure 200 and used to install a solder bump layer 260, and the solder bump layer 260 includes a plurality of solder bumps 261 which are able to be soldered onto the die device D. The second dielectric layers 240 are stacked sequentially along the stacking direction (e.g., Z axis direction) and directly sandwiched between the core layer 230 and the second solder mask layer 250. The second dielectric layers 240 are stacked sequentially along the stacking direction (e.g., Z axis direction) and directly sandwiched between the core layer 230 and the second solder mask layer 250. The second solder mask layer 250 that is opposite to the first solder mask layer 210, is a bottommost layer of the multilayer board structure 200 and used to install a ball grid array (BGA) layer 270, and the BGA layer 270 includes a plurality of solder balls 271 which are able to be soldered onto the circuit board P. However, the present disclosure is not limited to the number of the first dielectric layers 220 and the second dielectric layers 240, in another embodiment, the first dielectric layer 220 and the second dielectric layer 240 may be single in number, respectively. The wiring module 300 is located on the multilayer board structure 200, and the main ground area 100 is located within the lower portion 202 of the multilayer board structure 200. More specifically, the main ground area 100 is located on the second solder mask layer 250, and extends along a plane direction (e.g., X-Y axis direction). In more detail, the main grounding area 100 extends along the plane direction (e.g., X-Y axis direction), and the circuit module 300 extends along the stacking direction (e.g., Z axis direction).

In the embodiment, the wiring module 300 includes a differential pair circuit 310 and a plurality (e.g., 2) of ground via portions 320. The ground via portions 320 respectively penetrate through the multilayer board structure 200, that is, each of the ground via portions 320 sequentially passes through the first solder mask layer 210, the first dielectric layers 220, the core layer 230, the second dielectric layers 240 and the second solder mask layer 250. Each of the ground via portions 320 is electrically connected to the solder bump layer 260, the BGA layer 270 and the main grounding area 100 through solder pads 313, respectively. The differential pair circuit 310 includes two signal via portions 311 arranged among the ground via portions 320 (FIG. 1 and FIG. 2). Each of the signal via portions 311 penetrates through the multilayer board structure 200, and arranged among the ground via portions 320. Each of the signal via portions 311 is electrically connected to the solder bump layer 260 and the BGA layer 270 for enabling signals to be exchanged between the chip device D and the circuit board P. For example, these signal via portions 311 respectively are positive and negative electrode channels for performing the conduction of positive and negative signals moved along the stacking direction (e.g., Z axis direction), however, the present disclosure is not limited thereto.

The wiring substrate 10 further includes a plurality of first dummy metal pads 280. The first dummy metal pads 280 are embedded within the lower portion 202 (e.g., second dielectric layers 240), respectively extended in the plane direction (e.g., X-Y axis direction), and spaced arranged in the lower portion 202. The first dummy metal pads 280, the differential pair circuit 310 and the ground via portions 320 are respectively separated from one another, that is, the first dummy metal pads 280 are spaced arranged between the differential pair circuit 310 and the ground via portions 320, and between the signal via portions 311.

In this embodiment, each of the second dielectric layers 240 includes a first layer body 241, an anti-soldering pad 242 and the aforementioned first dummy metal pads 280. The anti-soldering pad 242 is placed on one surface of the first layer body 241 and formed with a continuous opening 243 exposing the second dielectric layers 240. The first dummy metal pads 280 are buried together inside the first layer body 241 and totally located in a range of the continuous opening 243 along with the signal via portions 311. These first dummy metal pads 280 are spaced arranged in accordance with the plane direction (e.g., X-Y axis direction). Since the first dummy metal pads 280, the signal via portions 311 and the main ground area 100 are respectively separated from one another, the first dummy metal pads 280, the wiring module 300 and the main ground area 100 are electrically isolated from one another. More specifically, all the first dummy metal pads 280 embedded in the second dielectric layers 240 overlap with each other in the stacking direction (e.g., Z axis direction, FIG. 1).

In this way, the first dummy metal pads 280 embedded in the second dielectric layers 240 can enhance the stress (e.g., 0.78 or 0.79) of the wiring substrate 10, thereby, reducing the risk of significant warpage of the wiring substrate 10 due to thermal expansion during testing. It is noted, although the first dummy metal pads 280 are embedded inside the first layer body 241, the present disclosure is not limited to that the first dummy metal pads 280 are partially exposed from a surface of the first layer body 241 or not.

More specifically, as shown in FIG. 1 and FIG. 2, some of the first dummy metal pads 280 grouped into a first group 281 of the first dummy metal pads 280 hereinafter are arranged in a region between the signal via portions 311. These first dummy metal pads 280 of the first group 281 are spaced arranged between the signal via portions 311 along the plane direction (e.g., X-Y axis direction). For example, theses first dummy metal pads 280 of the first group 281 are arranged according to an array of 2×2, that is, the first group 281 includes four first dummy metal pads 280 (see those in a dotted frame of the first group 281, FIG. 2), and these four first dummy metal pads 280 (see those in a dotted frame of the first group 281, FIG. 2) are spaced apart from each other to form a cross-shaped interval C1 connected to these signal via portions 311 and the continuous opening 243.

Other of the first dummy metal pads 280 grouped into a second group 282 of the first dummy metal pads 280 hereinafter are arranged in a region between one of the signal via portions 311 and one of the ground via portions 320. These first dummy metal pads 280 of each of the second groups 282 are spaced arranged between the one of the signal via portions 311 and the one of the ground via portions 320 along the plane direction (e.g., X-Y axis direction). For example, these first dummy metal pads 280 of each of the second groups 282 are arranged according to an array of 1×2, that is, each of the second groups 282 includes two first dummy metal pads 280 (see those in a dotted frame of the first group 282, FIG. 2), and these two first dummy metal pads 280 are spaced apart from each other to form a straight-line interval I1, and a long axis direction (e.g., Y axis) of the straight-line interval I1 extends through both of the signal via portions 311 and both of the ground via portions 320. These first dummy metal pads 280 of the first group 281 and one of the second groups 282 collectively surround one of the signal via portions 311. For example, the shapes of the first group 281 and the second groups 282 respectively have arc-shaped edges CR to surround the corresponding signal via portions 311.

Furthermore, as shown in FIG. 1, a diameter of one section 320A of each signal via portion 320 penetrated through the core layer 230 is greater than a diameter of another section 320B of the same signal via portion 320 penetrated through any of the second dielectric layers 240. A diameter of one section 311A of each signal via portion 311 penetrated through the core layer 230 is greater than a diameter of another section 311B of the same signal via portion 320 penetrated through any of the second dielectric layers 240.

Since an appropriate spacing distance between any signal via portion 311 and an adjacent one of the first dummy metal pads 280, the signal via portion 311 does not generate parasitic inductance and capacitance compensation, thereby providing appropriate signal integrity. For example, a minimum straight spacing distance G1 between one of the signal via portions 311 and one of the first dummy metal pads 280 of the first group 281 (or the second group 282) is between 30 and 125 microns, however, the present disclosure is not limited thereto. The minimum straight spacing distance G2 between any two adjacent ones of the first dummy metal pads 280 in the first group 281 (or the second group 282) is between 30 and 125 microns. However, the present disclosure is not limited thereto.

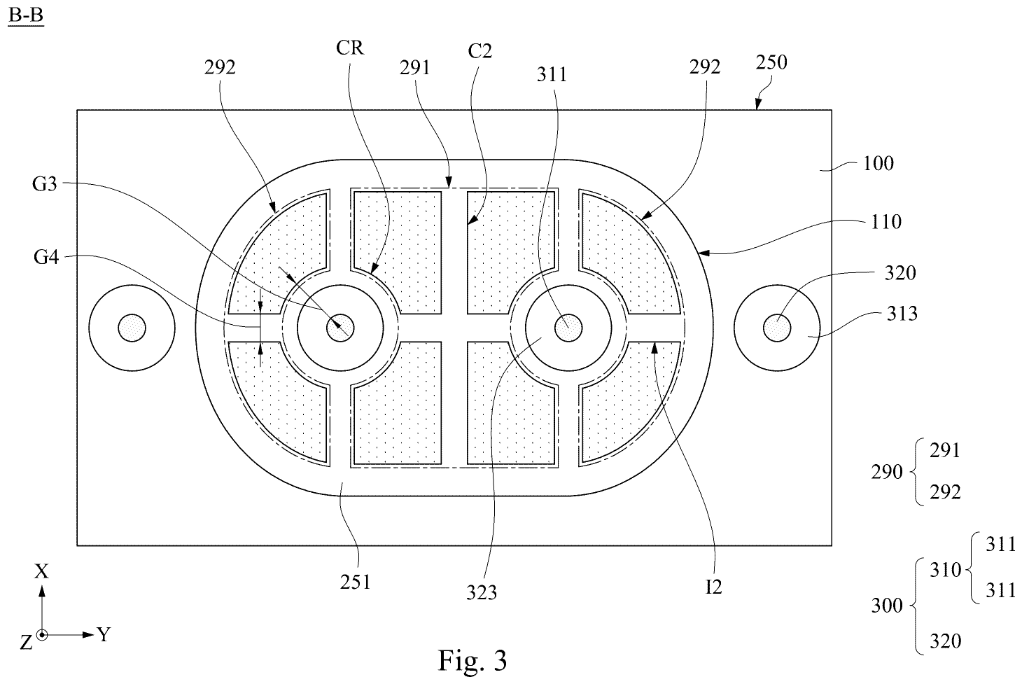

FIG. 3 is a cross-sectional view of the wiring substrate 10 in FIG. 1 viewed along a line BB. Refer to FIG. 1 to FIG. 3, the second solder mask layer 250 includes a second layer body 251 and a plurality of second dummy metal pads 290 collectively embedded within the second layer body 251 and spaced arranged in the plane direction (e.g., X-Y axis direction). The second dummy metal pads 290 are electrically isolated from the wiring module 300 and the main ground area 100. The main ground area 100 surrounds the differential pair circuit 310 and the second dummy metal pads 290 on one surface of the second solder mask layer 250. More specifically, the main grounding region 100 defines a closed opening 110 on the second solder mask layer 250. The circuit module 300 and the second dummy metal piece 290 are completely located within the range of the closed opening 110.

More specifically, any of the second dummy metal pads 290 in the second solder mask layer 250 overlaps one of the first dummy metal pads 280 in the second dielectric layers 240 along the stacking direction (e.g., Z axis direction, FIG. 1).

Thus, the second dummy metal pads 290 embedded in the second solder mask layer 250 can enhance the stress (e.g., 0.78 or 0.79) of the wiring substrate 10, thereby, reducing the risk of significant warpage of the wiring substrate 10 due to thermal expansion during testing. It is noted, although the second dummy metal pads 290 are embedded inside the second layer body 251, the present disclosure is not limited to that the second dummy metal pads 290 are partially exposed from a surface of the second layer body 251 or not.

More specifically, as shown in FIG. 3, some of the second dummy metal pads 290 grouped into a first group 291 of the second dummy metal pads 290 hereinafter are arranged in a region between the signal via portions 311. These second dummy metal pads 290 of the first group 291 are spaced arranged between the signal via portions 311 along the plane direction (e.g., X-Y axis direction). For example, theses second dummy metal pads 290 of the first group 291 are arranged according to an array of 2×2, that is, the first group 291 includes four second dummy metal pads 290 (see those in a dotted frame of the second group 281, FIG. 2), and these four second dummy metal pads 290 are spaced apart from each other to form a cross-shaped interval C2 connected to these signal via portions 311 and the closed opening 110. The cross-shaped interval C2 of the second solder mask layer 250 is overlapped with the cross-shaped interval C1 of each of the second dielectric layers 240 in the stacking direction (e.g., Z axis direction, FIG. 1). A width W2 of one of the second dummy metal pads 290 is smaller than a width W1 of one of the first dummy metal pads 280 which is overlapped with the second dummy metal pad 290 in the stacking direction (e.g., Z axis direction, FIG. 1).

Other of the second dummy metal pads 290 grouped into a second group 292 of the second dummy metal pads 290 hereinafter are arranged in a region between one of the signal via portions 311 and one of the ground via portions 320. These second dummy metal pads 290 of each of the second groups 292 are spaced arranged between the one of the signal via portions 311 and the one of the ground via portions 320 along the plane direction (e.g., X-Y axis direction). The wiring module 300, the second dummy metal pads 290 of the first group 292 and the second group 292 are completely located within the range of the closed opening 110. For example, theses second dummy metal pads 290 of each of the second groups 292 includes two second dummy metal pads 290 (see those in a dotted frame of the second groups 292, FIG. 2), and these two second dummy metal pads 290 (see those in a dotted frame of the second group 292, FIG. 2) are spaced apart from each other to form a straight-line interval I2, and a long axis direction (e.g., Y axis) of the straight-line interval I2 extends through both of the signal via portions 311 and both of the ground via portions 320. Each of the straight-line interval I2 of the second solder mask layer 250 is overlapped with the straight-line interval I1 of each of the second dielectric layers 240 along the stacking direction (e.g., Z axis direction, FIG. 2).

These second dummy metal pads 290 of the first group 291 and one of the second groups 292 collectively surround one of the signal via portions 311. For example, the shapes of the first group 291 and the second groups 292 respectively have arc-shaped edges CR to surround the corresponding signal via portions 311.

Since an appropriate spacing distance between any signal via portion 311 and an adjacent one of the second dummy metal pads 290, the signal via portion 311 does not generate parasitic inductance and capacitance compensation, thereby providing appropriate signal integrity. For example, a minimum straight spacing distance G3 between one of the signal via portions 311 and one of the second dummy metal pads 290 of the first group 291 (or the second group 292) is between 30 and 125 microns. However, the present disclosure is not limited thereto. The minimum straight spacing distance G4 between any two adjacent ones of the second dummy metal pads 290 in the first group 291 (or the second group 292) is between 30 and 125 microns, however, the present disclosure is not limited thereto.

In this embodiment, the core layer 230 is made of insulating material; the dielectric layer is an unreinforced resin layer, such as an Ajinomoto Build-up Film, ABF; a dummy metal sheet such as a copper or aluminum pad; the wiring substrate 10 may be implemented in a field of a serializer/deserializer (SerDes) system, however, the present disclosure is not limited thereto.

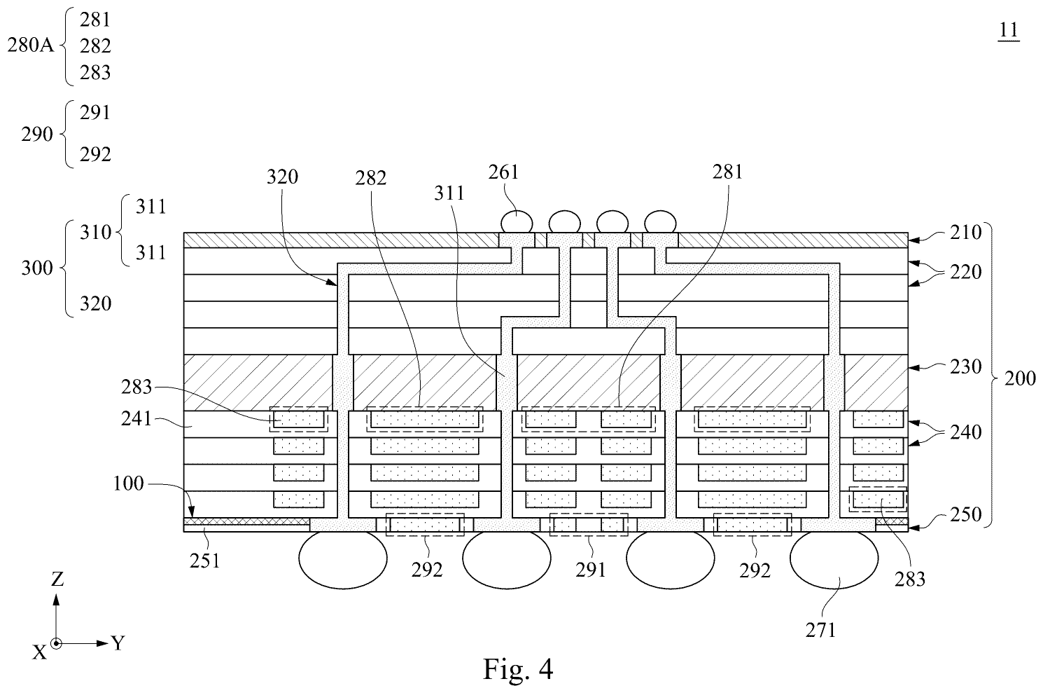

FIG. 4 is a schematic side view of a wiring substrate I1 according to an embodiment of the present disclosure. As shown in FIG. 4, the wiring substrate I1 is substantially the same to the wiring substrate 10 described above, except that in addition to the first group 281 and the second group 282, a third group 283 of the first dummy metal pads 280 is further provided in the embodiment.

Specifically, still other of the first dummy metal pads 280A further grouped into a third group 283 of the first dummy metal pads 280 hereinafter are located on the other side of the ground via portions 320 away from the differential pair circuit 310, and located within a range of the continuous opening 243 surrounded by the anti-soldering pad 242 (FIG. 2). The first dummy metal pads 280A of the third group 283 are spaced arranged along the plane direction (e.g., X-Y axis direction). The first dummy metal pads 280A of the third group 283 are located between those of the second group 282 and those of the third group 283, and collectively surrounded by those of the second group 282 and those of the third group 283.

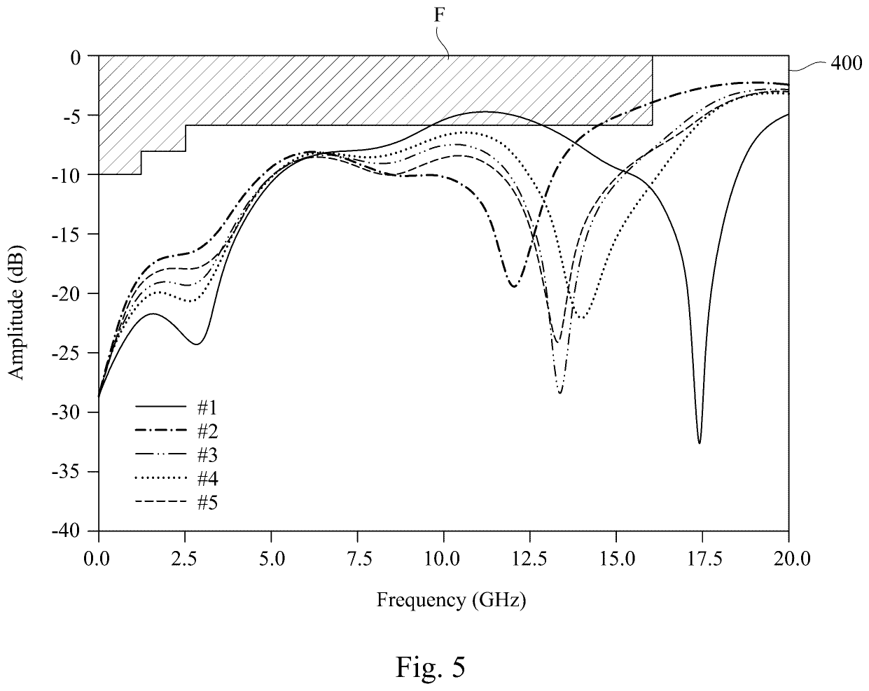

FIG. 5 is a frequency-intensity table 400 of various the wiring substrates, which has curves #1 to #5 therein, and the curves #1 to #4 are conventional wiring substrates, and the curve #5 is the wiring substrate 10 of the above embodiment. In this way, as shown in FIG. 5, it can be seen from the test results that the curves #1 to #4 of the conventional wiring substrates are all shown to be in a unqualified area F in the frequency-intensity table 400, that is, these conventional wiring substrates having higher return loss which is considered to fail to provide better signal integrity. Although the curves #3˜#4 of the conventional technology do not locate into the unqualified area F in the frequency-intensity table 400, the fluctuation range is too large to exceed the performance of the curve #5 of this disclosure.

Thus, through the construction of the embodiments above, as metal being broken into a plurality of dummy metal pads distributed at intervals around the wiring module in the wiring substrate, the wiring substrate of the disclosure is able to strike a balance between the stress and the signal integrity of the substrate structure so as to not only reduce the risk of damage to the wiring substrate, but also maintain signal transmission performance conforming to requirements.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A wiring substrate, comprising:
a multilayer board structure divided into an upper portion and a lower portion by a core layer interposed therein, wherein the upper portion is used to connect to a die device, and the lower portion is used to connect to a circuit board;
a main ground area located within the lower portion of the multilayer board structure;
a wiring module located on the multilayer board structure, and comprising a differential pair circuit and a plurality of ground via portions, the ground via portions that are electrically connected to the main ground area, respectively, and the differential pair circuit having two signal via portions arranged among the ground via portions; and
a plurality of first dummy metal pads embedded in the lower portion, electrically isolated from the wiring module, spaced arranged between the differential pair circuit and the ground via portions, and between the signal via portions.

2. The wiring substrate of claim 1, wherein the first dummy metal pads are spaced arranged within the lower portion in a plane direction and a stacking direction, respectively, wherein the plane direction is orthogonal to the stacking direction.

3. The wiring substrate of claim 1, wherein some of the first dummy metal pads collectively surrounds one of the signal via portions.

4. The wiring substrate of claim 1, wherein a minimum straight spacing distance between one of the signal via portions and one of the first dummy metal pads is between 30 and 125 microns.

5. The wiring substrate of claim 1, further comprising:
a plurality of second dummy metal pads that are electrically isolated from the wiring module,
wherein one side of the lower portion opposite to the upper portion is provided with a solder mask layer connected to the circuit board through a BGA layer, and the second dummy metal pads are embedded in the solder mask layer, and spaced arranged between the differential pair circuit and the ground via portions, and between the signal via portions.

6. The wiring substrate of claim 5, wherein a minimum straight spacing distance between one of the signal via portions and one of the second dummy metal pads is between 30 and 125 microns.

7. The wiring substrate of claim 5, wherein one of the first dummy metal pads and one of the second dummy metal pads are overlapped with each other in a stacking direction.

8. The wiring substrate of claim 5, wherein a width of one of the second dummy metal pads is smaller than a width of one of the first dummy metal pads.

9. The wiring substrate of claim 5, wherein a diameter of one section of one of the signal via portions in the core layer is greater than a diameter of another section of the one of the signal via portions in the lower portion.

10. A wiring substrate, comprising:
a multilayer board structure comprising a core layer, a first solder mask layer, a second solder mask layer, at least one first dielectric layer and at least one second dielectric layer, the core layer that is stacked between the at least one first dielectric layer and the at least one second dielectric layer, a thickness of the core layer that is greater than a thickness of the at least one second dielectric layer, the at least one first dielectric layer that is stacked between the first solder mask layer and the core layer, the first solder mask layer that is used to install a solder bump layer thereon, the at least one second dielectric layer that is stacked between the second solder mask layer and the core layer, the second solder mask layer that is used to arrange a BGA layer thereon, the at least one second dielectric layer comprising a first layer body and a plurality of first dummy metal pads embedded within the first layer body and spaced arranged within the first layer body in a plane direction;
a main ground area located within the multilayer board structure; and
a wiring module comprising a differential pair circuit and a plurality of ground via portions, each of the ground via portions penetrating through the multilayer board structure, and electrically connected to the solder bump layer, the BGA layer and the main ground area, respectively, the differential pair circuit comprising two signal via portions, each of the signal via portions penetrating through the multilayer board structure, arranged among the ground via portions, and electrically connected to the solder bump layer and the BGA layer,
wherein the first dummy metal pads are electrically isolated from the wiring module, and separated from the differential pair circuit and the ground via portions, respectively.

11. The wiring substrate of claim 10, wherein a first group of the first dummy metal pads is spaced arranged between the signal via portions, and a second group of the first dummy metal pads is spaced arranged between one of the signal via portions and one of the ground via portions.

12. The wiring substrate of claim 11, wherein the first group and the second group of the first dummy metal pads collectively surround one of the signal via portions.

13. The wiring substrate of claim 11, wherein one of the ground via portions is arranged between the second group of the first dummy metal pads and a third group of the first dummy metal pads.

14. The wiring substrate of claim 10, wherein a minimum straight spacing distance between one of the signal via portions and one of the first dummy metal pads is between 30 and 125 microns.

15. The wiring substrate of claim 10, wherein the at least one second dielectric layer comprises a plurality of second dielectric layers stacked sequentially in a stacking direction, and directly sandwiched between the core layer and the second solder mask layer, and the stacking direction is orthogonal to the plane direction,
wherein the first dummy metal pads arranged within the second dielectric layers are overlapped with each other in the stacking direction.

16. The wiring substrate of claim 10, wherein the second solder mask layer comprises a second layer body and a plurality of second dummy metal pads embedded within the second layer body and spaced arranged in the plane direction,
wherein the second dummy metal pads are electrically isolated from the wiring module, and separated from the differential pair circuit and the ground via portions, respectively.

17. The wiring substrate of claim 16, wherein a first group of the second dummy metal pads is spaced arranged between the signal via portions, and a second group of the second dummy metal pads is spaced arranged between one of the signal via portions and one of the ground via portions,
wherein the main ground area is located on the second solder mask layer to surround the differential pair circuit and the second dummy metal pads.

18. The wiring substrate of claim 17, wherein a minimum straight spacing distance between one of the signal via portions and one of the second dummy metal pads is between 30 and 125 microns.

19. A wiring substrate, comprising:
a multilayer board structure divided into an upper portion and a lower portion by a core layer interposed therein, the upper portion is used to connect to a die device, and the lower portion comprising a solder mask layer, a BGA layer and at least one dielectric layer, the at least one dielectric layer that is stacked between the solder mask layer and the core layer, and the solder mask layer is located between the BGA layer and the at least one dielectric layer, and the BGA layer is used to connect to a circuit board;
a main ground area located within the lower portion of the multilayer board structure;
a wiring module comprising a differential pair circuit and a plurality of ground via portions, each of the ground via portions penetrating through the multilayer board structure and electrically connected to the main ground area, the differential pair circuit comprising two signal via portions, each of the signal via portions penetrating through the multilayer board structure, arranged among the ground via portions; and
a plurality of dummy metal pads embedded in one of the solder mask layer and the at least one dielectric layer, and arranged sequentially in a plane direction,
wherein the dummy metal pads are spaced arranged between the differential pair circuit and the ground via portions, and between the signal via portions, and electrically isolated from the wiring module.

20. The wiring substrate of claim 19, wherein one group of the dummy metal pads is spaced arranged between the signal via portions, and another group of the dummy metal pads is spaced arranged between one of the signal via portions and one of the ground via portions, and the one group and the another group of the dummy metal pads collectively surround one of the signal via portions.
